(19) United States
(12) Patent Application Publication
(10) Pub. No.: US 2009/0045528 A1
(43) Pub. Date: Feb. 19, 2009

(54) Semiconductor device

(75) Inventors: Pao-Yun Tang, Jhongli City (TW); Wei-Hao Sun, Taipei (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HannStar Display Corporation, Tao-Yuan Hsien (TW)

(21) Appl. No.: 11/986,707

(22) Filed: Nov. 26, 2007

(30) Foreign Application Priority Data
Aug. 17, 2007 (TW) 096130588

(51) Int. Cl. H01L 23/48

(52) U.S. Cl. 257/783; 257/E23.01

(57) ABSTRACT

An electronic structural member or a semiconductor device having conductive bumps is provided. The conductive bump includes an organic buffer layer with an undercut structure, and the conductive bump is deformable during the bonding process so as to compensate the height difference between the conductive bumps. In addition, an adhesive is further disposed between the IC chip and the substrate, and partial adhesive fills in the undercut structure, such that not only the adhesive area can be increased to enhance the bonding force between the IC chip and the substrate, but the return force of the adhesive can be reduced.

This application claims the benefit of Taiwan Patent Application No. 096130588, filed on Aug. 17, 2007, which is hereby incorporated by reference for all purposes as if fully set forth herein.

### BACKGROUND OF THE INVENTION

1. Field of the Invention

The present invention relates to an electronic structural member or a semiconductor device having conductive bumps, especially for an electronic structural member or a semiconductor device having a conductive bump with undercut structures and balance functions.

2. Related Art

In the manufacturing field of electronic structural members or semiconductor devices, it contains many complicated manufacturing processes, especially the processes for Liquid Crystal Display (LCD). Generally speaking, LCDs are produced by connecting a plurality of LCD driver chips and a plurality of driver and control circuit chips on the peripheral portions of glass substrates. The contact pads of the chips align accurately and connect to the leads on the glass substrates for providing well conductivity properties, so that the LCDs can display correct images through the well signal transmission.

To achieve above mentioned accurate alignment and well conductivity properties, many kinds of bonding methods have been searched and developed. Two popular methods of them are Tape Automated Bonding (TAB) and Chip on Glass (COG). Similarly, the above methods may apply to other kinds of electronic structural members or semiconductor devices, so as to connect chips to circuit boards or other conductive leads. In the applications of bonding methods, due to the development of conductive films, the density of connection points is therefore increased. However, an electrical short problem between adjacent connection points may occur.

Moreover, in the conventional COG technologies, the adopted gold bump structure has a higher Young's modulus. In the bonding process, the passivation layer may easily break. Therefore, a composite bump structure is utilized to solve the problem of high Young's modulus. However, because the metal film is too thin, it may be broken during the four-point probe test, so as to effect the electrical connection between the bumps and connection points.

In addition, in order to increase the mechanical stability, U.S. Pat. No. 7,176,583 disclosed a barrier layer metal in which the process time for wet etching is reduced to prevent forming an undercut structure and reduce the pitch of bumps. In U.S. Published Patent No. 2007/0023919, it disclosed an electrically conductive adhesion/barrier layer having a gap or an undercut structure and formed between the passivation layer on the contact pad and the bonding metal layer.

However, both U.S. Pat. No. 7,176,583 and U.S. Published Patent No. 2007/0023919 did not disclose how to deal with the breaking of the passivation layer and the cracking of the metal film, which occurred in the conventional COG technologies. Therefore, how to solve the above mentioned problems is a principal challenge for the present invention.

### SUMMARY OF THE INVENTION

Accordingly, the present invention is directed to an electronic structural member or a semiconductor device having conductive bumps with auto balance functions. Without increase the number of photo masks and design costs, a dry etching process is applied to the side edges of an organic buffer layer to form an undercut structure; therefore the adhesive force between the conductive bump and the adhesive can be increased, and the return force of the connecting points can be reduced too, so as to prevent the breaking of the passivation layer and the cracking of the metal film, and to avoid the phenomenon of the significant contact resistance difference due to an unbalanced applied force.

The present invention is to provide an electronic structural member or a semiconductor device having conductive bumps. The conductive bump comprises an organic buffer layer that is deformable to be able to compensate the height difference between the bumps during the bonding process, such that the poor bonding problem due to the height difference can be prevented. In addition, the undercut structure formed on the side edges of the organic buffer layer can let partial adhesive permeated into the space between the passivation layer and the substrate, so as to reduce the return force in the bonding points, increase adhesive force, and enhance the reliability of the products.

In the present invention, because the conductive bump has an organic buffer layer with low Young's modulus and an undercut structure in its side edges; therefore the conductive bumps can effectively distribute the bonding force during the bonding process, such that the chip and the substrate can be tightly bonded and the phenomenon of unbalanced contact resistance can also be avoided.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1 is a schematic diagram showing an LCD drive chip bonded to a glass substrate according to the present invention;

FIG. 2 is an enlarged cross section view showing the LCD drive chip bonded to the glass substrate according to the present invention;

FIG. 3A is a top schematic diagram of a first embodiment according to the present invention;

FIG. 3B is a cross section view of the first embodiment according to the present invention;

FIG. 4 is a schematic diagram of a second embodiment according to the present invention;

FIG. 5A is a top schematic diagram of a third embodiment according to the present invention;

FIG. 5B is a cross section view of the third embodiment according to the present invention;

FIG. 6 is a relative schematic diagram showing the adhesive filled in the undercut structure during the bonding process according to the first embodiment of the present invention; and

FIG. 7 is a view of the whole structure and the surrounding structure under a high magnification.

### DETAILED DESCRIPTION OF THE INVENTION

Hereafter, the embodiments of the present invention will be described with reference to accompanying drawings.

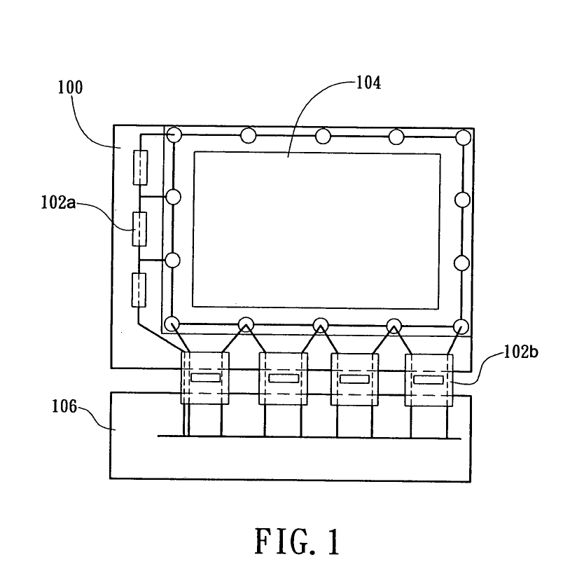

Referring to the FIG. 1, it is a prefer embodiment of the present invention, and it is an electronic structural member or a semiconductor device having conductive bumps. For easy explanation, in the embodiment, a liquid crystal display (LCD) is taken as an example. The LCD comprises a liquid crystal display area 104, a chip-on-glass (COG) driver circuit 102a, and a chip-on-film (COF) driver circuit 102b. The liquid crystal display area 104 and the COG driver circuit 102a are disposed on the middle area and the peripheral area of a glass substrate 100, respectively, and the COF driver circuit 102 is disposed on a flexible thin film connected to the glass substrate 100 and a printed circuit board (PCB) 106.

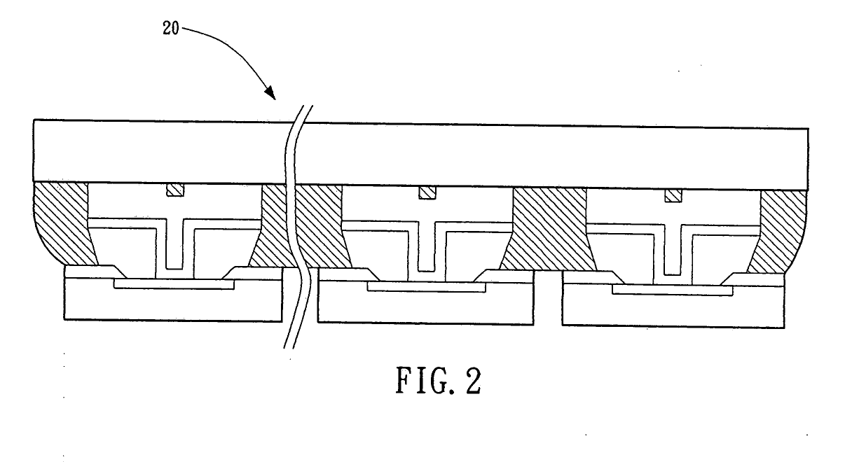

Referring to the FIG. 2, it is a partial cross section view of the COG driver circuit 102a in the FIG. 1. For introduction purpose, the conductive bump structure 20 shown in FIG. 2 is displaced upside-down.

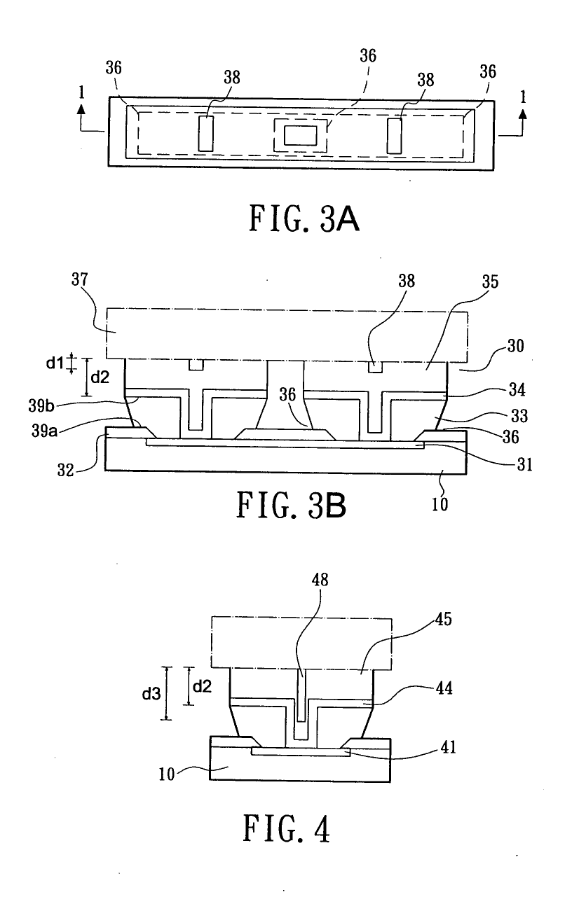

Referring to the FIGS. 3A and 3B, FIG. 3A is a top schematic diagram of a first embodiment according to the present invention, and FIG. 3B is a cross section view along line 1-1 of the first embodiment. Please referring to the FIGS. 3A and 3B, the conductive bump structure 30 comprises an IC chip 10, a contact pad 31 formed on or embodied in the IC chip 10, a passivation layer 32 partially overlapped on the contact pad 31, an organic buffer layer 33 formed on the contact pad 31 and having an undercut structure 36, a first conductive layer 34 formed on the organic buffer layer 33 and connected to the contact pad, and a second conductive layer 35 formed on the first conductive layer 34.

Here, the first conductive layer 34 may comprise a first sub-layer and a second sub-layer, and the second sub-layer is stacked on the first sub-layer. The material of the first conductive layer 34 may be Titanium (Ti), Tungsten (W), Gold (Au), their alloy or a combination thereof, and the material of the second conductive layer 35 may be Gold (Au), Tin, Lead, their alloy, and a combination thereof.

In the embodiment of the present invention, the IC chip 10 is applied to the COG driver circuit 102a and connected to an external device through the contact pad 31. However, in other electronic structural member or semiconductor device applications, the IC chip 10 may be other kinds of chips. In most applications, the contact pad 31 can be made of Aluminum (Al), Aluminum alloy, or their combination. The peripheral area of the contact pad 31 is covered with the passivation layer 32 which is used to space apart each contact pad on the IC chip 10 and prevent the circuits of the IC chip 10 from outside pollution. The passivation layer is made of dielectric materials such as inorganic oxides of SiO2, Si3N4, SiON, and so on.

The organic buffer layer 33 is formed on the IC chip 10 and composed of polymers, such as photoresist materials—Polyimide and so on. The organic buffer layer 33 is connected to the first conductive layer 34 or the second conductive layer 35 so as to reduce the Young's modulus of the whole conductive bump; therefore it not requires a high bonding force during the bonding process. That is, by means of the deformation of the organic buffer layer 33, the tolerance of the conductive bump for the height difference can be increased, such that the conductive bumps can be sufficiently bonded with the conductive points (not shown in FIGS. 3A and 3B) of the glass substrate 37. Therefore, the impact for the IC chip 10 can be mitigated during the bonding process. The organic buffer layer 33 is formed by means of spin coating, and the undercut structure 36 of the organic buffer layer 33 is formed by adding a dry etching process. In addition, because the conductive bump is utilized as an protection in the dry etching process, the redundant organic buffer layer 33 can be directly removed by plasma or reactive ion etching (RIE) without additional photo mask designs and costs.

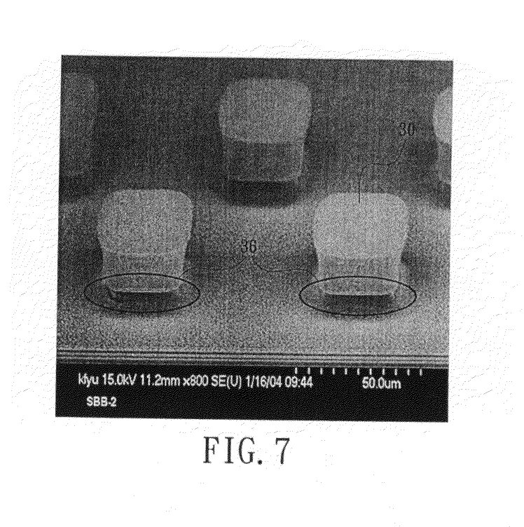

The organic buffer layer 33 comprises a first contact surface 39a corresponding to the contact pad 31 and the passivation layer 32, and a second contact surface 39b corresponding to the first conductive layer 34. The area of the first contact surface 39a is smaller than the area of the second contact surface 39b. The projection of the first contact surface 39a is within the projection of the second contact surface 39b so as to form the undercut structure 36. Preferably, the undercut structure 36 is a surrounding structure (please refer to FIG. 7), and the contact surfaces are paralleled to the IC chip.

Referring to FIGS. 3A and 3B, the above-mentioned second conductive layer 35 has an accommodation space 38 corresponding to the bonding area between the first conductive layer 34 and the contact pad 31. The thickness of the second conductive layer 35 is larger than the thickness of the organic buffer layer 33. Therefore, the depth d1 of the accommodation space 38 is smaller than the thickness d2 of the first conductive layer 34 and the second conductive layer 35.

Referring to FIG. 4, the above-mentioned second conductive layer 45 has an accommodation space 48 corresponding to the bonding area between the first conductive layer 44 and the contact pad 41. The thickness of the second conductive layer 45 is less than the thickness of the organic buffer layer 43. Therefore, the depth d3 of the accommodation space 48 is larger than the thickness d2 of the first conductive layer 44 and the second conductive layer 45.

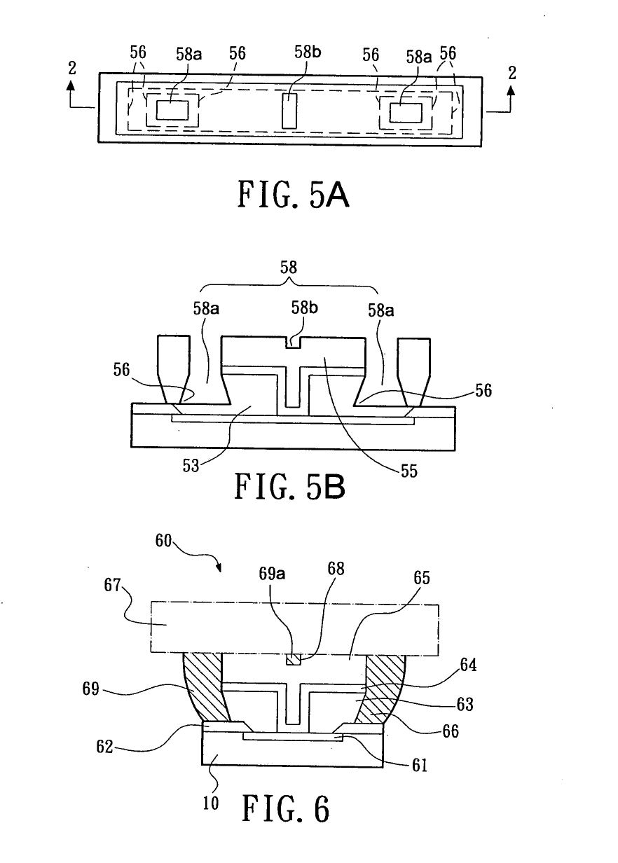

In addition, FIG. 5A is a top schematic diagram of a third embodiment according to the present invention, and FIG. 5B is a cross section view along line 2-2 of the FIG. 5A according to the present invention. Please referring to FIGS. 5A and 5B, the accommodation space 58 further comprises a first cavity 58a and a second cavity 58b. The first cavity 58a is located in the organic buffer layer 53 and the second conductive layer 55, and the second cavity 58b is located in the second conductive layer 55. The bottom section of the first cavity 58a is lager than its opening section, or the opening section projection of the first cavity 58a is located within its bottom section projection, so as to form the undercut structure 56 in the side edges of the organic buffer layer 53 and the undercut structure 56 is a surrounding structure.

Referring to FIG. 6, it is an electronic structural member or a semiconductor device of the present invention. The bump structure 60 comprises an IC chip 10, a contact pad 61 formed on or embodied in the IC chip 10, a passivation layer 62 partially overlapped on the contact pad 61, an organic buffer layer 63 formed on the contact pad 61 and having a undercut structure, a first conductive layer 64 formed on the organic buffer layer 63 and connected to the contact pad 61, a second conductive layer 65 formed on the first conductive layer 64, and a substrate 67 and an adhesive 69. The substrate 67 is disposed on the second conductive layer 64, and the adhesive 69 is disposed or permeated into the space between the substrate 67 and the IC chip 10.

The undercut structure 66 is formed by a dry etching process, and is a surrounding structure. The second conductive layer 65 has an accommodation space 68, and the adhesive 69 includes a filled portion 69a filled in the accommodation space 68, so as to increase the adhesive area with the substrate for enhancing the adhesive force. The material of the adhesive may be a conductive paste or a nonconductive paste, such as anisotropic conductive paste (ACP), anisotropic conductive film (ACF), nonconductive paste (NCP), or nonconductive film (NCF).

In addition, the present invention discloses an electronic structural member or a semiconductor device having conductive bumps. The conductive bump comprises an organic buffer layer that is deformable to compensate the height difference between the bumps during the bonding process, so as to solve the problem of poor bonding. Besides, the undercut structure formed on the side edges of the organic buffer layer can let partial adhesive penetrated into the space between the passivation layer and the substrate, so as to reduce the return force, increase adhesive force, and enhance the reliability of the products.

When bonding the IC chip 10 with the substrate 67, an external force is needed to apply thereon; therefore the organic buffer layer will be deformed to compensate the height difference between the conductive layers 64, 65 so as to solve the problem of poor bonding. At same time, partial adhesive 69 is filled in the undercut structure 66 for increasing the adhesive area and enhancing the adhesive force. Also, the bonding force can be decentralized to reduce the return force of the adhesive 69. Therefore, the impact for the IC chip 10 can be mitigated during the bonding process, and the problem of no place to disperse for the return force of the adhesive because of applying an over bonding force can be solved.

Because the electronic structural member or the semiconductor device having conductive bumps of the present invention has an organic buffer layer and an undercut structure, the Young's modulus of the total conductive bumps is largely reduced. And the organic buffer layer is deformable during the bonding process, such that the height difference between the bumps can be compensated. In addition, when an external force is applied during the bonding process, the adhesive between the IC chip and the substrate can partially fill in the undercut structure, which not only increases an adhesive area to enhance the adhesive force but partially disperse the bonding force such that the return force of the adhesive generated by the place between the IC chip and the substrate can be reduced. Hence, applying a large bonding force becomes not necessary.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. An electronic structural member, comprising:
an IC chip;
a contact pad formed on the IC chip;
a passivation layer partially overlapped on the contact pad;
an organic buffer layer formed on the contact pad and having an undercut structure;
a first conductive layer formed on the organic buffer layer and connected to the contact pad; and
a second conductive layer formed on the first conductive layer.

2. The electronic structural member as claimed in claim 1, wherein the organic buffer layer comprises a first contact surface corresponding to the contact pad and the passivation layer and a second contact surface corresponding to the first conductive layer.

3. The electronic structural member as claimed in claim 2, wherein an area of the first contact surface is smaller than an area of the second contact surface so as to form the undercut structure.

4. The electronic structural member as claimed in claim 2, wherein a projection of the first contact surface is within a projection of the second contact surface so as to form the undercut structure.

5. The electronic structural member as claimed in claim 2, wherein the first contact surface and the second contact surface are parallel to the IC chip.

6. The electronic structural member as claimed in claim 1, wherein the undercut structure is a surrounding structure.

7. The electronic structural member as claimed in claim 1, wherein the first conductive layer comprises a first sub-layer and a second sub-layer stacked on the first sub-layer.

8. The electronic structural member as claimed in claim 1, wherein the second conductive layer includes an accommodation space.

9. The electronic structural member as claimed in claim 8, wherein the accommodation space is corresponding to a bonding area between the first conductive layer and the contact pad.

10. The electronic structural member as claimed in claim 8, wherein the accommodation space includes a first cavity and a second cavity.

11. The electronic structural member as claimed in claim 10, wherein the first cavity is located in the organic buffer layer and the second conductive layer.

12. The electronic structural member as claimed in claim 10, wherein the second cavity is located in the second conductive layer.

13. The electronic structural member as claimed in claim 10, wherein a bottom section of the first cavity is lager than an opening section of the first cavity.

14. The electronic structural member as claimed in claim 10, wherein an opening section projection of the first cavity is located within a bottom section projection of the first cavity.

15. The electronic structural member as claimed in claim 8, wherein a depth of the accommodation space is larger than a thickness of the first conductive layer and the second conductive layer.

16. The electronic structural member as claimed in claim 8, wherein a depth of the accommodation space is smaller than a thickness of the first conductive layer, the second conductive layer, and the organic buffer layer.

17. A semiconductor device, comprising:
an IC chip;
a contact pad formed on the IC chip;
a passivation layer partially overlapped on the contact pad;
an organic buffer layer formed on the contact pad and having an undercut structure;
a first conductive layer formed on the organic buffer layer and connected to the contact pad; and
a second conductive layer formed on the first conductive layer;
a substrate disposed on the second conductive layer; and
an adhesive disposed between the substrate and the IC chip.

18. The electronic structural member as claimed in claim 17, wherein the second conductive layer includes an accommodation space and the adhesive includes a filled portion filled in the accommodation space.

19. The electronic structural member as claimed in claim 17, wherein a material of the adhesive is a conductive paste or a nonconductive paste.

20. The electronic structural member as claimed in claim 17, wherein a material of the adhesive is selected from a group consisting of an anisotropic conductive paste (ACP), an anisotropic conductive film (ACF), a nonconductive paste (NCP), and a nonconductive film (NCF).
